(19) United States
(12) Patent Application Publication
(10) Pub. No.: US 2021/0098640 A1
(43) Pub. Date: Apr. 1, 2021

(54) SYSTEM AND METHOD FOR SOLAR CELL ARRANGEMENT ON A VEHICLE

(71) Applicant: Aperta Motors, Corp., San Diego, CA (US)

(72) Inventors: Jason HILL, Long Beach, CA (US); Steve FAMBRO, Carlsbad, CA (US); Chris ANTHONY, San Diego, CA (US); Darren McKEAGE, Carlsbad, CA (US)

(73) Assignee: Aptera Motors, Corp., San Diego, CA (US)

(21) Appl. No.: 17/035,244

(22) Filed: Sep. 28, 2020

Related U.S. Application Data
(60) Provisional application No. 62/907,319, filed on Sep. 27, 2019.

(51) Int. Cl. H01L 31/0463; H02S 30/10; H01L 31/048; H02S 40/38

(52) U.S. Cl. CPC H01L 31/0463; H02S 30/10; B60K 16/00; H02S 40/38; H01L 31/048

(57) ABSTRACT

Vehicles having a plurality of solar cells arranged at an acute angle relative to a longitudinal axis of the vehicle. The solar cells may having an irregular octagon shape and may be more flexible along one axis of symmetry relative to the other axis of symmetry.

### TECHNICAL FIELD

Embodiments disclosed herein are generally related to vehicles, and more particularly to solar powered vehicles.

### BACKGROUND

In an effort to reduce emissions, automobile manufacturers are looking for alternative methods to power vehicles, such as automobiles. One form of alternative power source is solar power. To make use of solar power, solar cells are typically used. Multiple solar cells can be affixed to the exterior body of the vehicle to harvest energy from the sun and store that energy in batteries on the vehicle.

In order to maximize the generation of electricity, manufacturers attach the solar cells to the vehicle in such a way that places the most cells into the smallest area on the exterior body of the vehicle. Solar cells generally have a rectilinear shape, so manufacturers align the sides of the solar cells with the longitudinal axis of the vehicle. That is, the straight sides of the solar cells are aligned to be parallel or orthogonal with the longitudinal axis of the vehicle. Since solar cells are generally planar and are not very flexible in the directions parallel with the sides of the solar cell, solar cells lack durability and are prone to breaking. The general inflexibility of the solar cells along the primary axes can limit the design choices for the exterior of the vehicle. For example, making the exterior body more rounded, in an effort to reduce wind resistance, can be limited by the inflexibility of the solar cells.

Therefore, an efficient arrangement of solar cells having an improved design with suitable flexibility is required.

### BRIEF DESCRIPTION OF THE SEVERAL VIEWS OF THE DRAWINGS

For a more complete understanding of the present disclosure and certain features thereof, reference is now made to the following description, in conjunction with the accompanying figures briefly described as follows:

FIG. 1A presents a top plan view of a solar powered vehicle, in accordance with one example embodiment of the disclosure.

FIG. 1B is a top perspective view of the solar powered vehicle of FIG. 1A, in accordance with one example embodiment of the disclosure.

FIG. 1C is a side elevation view of the solar powered vehicle of FIG. 1A, in accordance with one example embodiment of the disclosure.

FIG. 1D is a front elevation view of the solar powered vehicle of FIG. 1A, in accordance with one example embodiment of the disclosure.

FIG. 1E is a rear elevation view of the solar powered vehicle of FIG. 1A, in accordance with one example embodiment of the disclosure.

FIG. 2 is a top plan view of a solar cell for use with the solar powered vehicle of FIG. 1A, in accordance with one example embodiment of the disclosure.

FIG. 3A is a schematic of an encapsulation layer for use with the solar powered vehicle of FIG. 1A, in accordance with one example embodiment of the disclosure.

FIG. 3B is a schematic of an encapsulation layer for use with the solar powered vehicle of FIG. 1A, in accordance with one example embodiment of the disclosure.

FIG. 4 is a schematic of a solar powered vehicle, in accordance with one example embodiment of the disclosure.

### DETAILED DESCRIPTION OF THE EXAMPLE EMBODIMENTS

Example embodiments of a solar cell arrangement on a vehicle will be described more fully hereinafter with reference to the accompanying drawings, in which example embodiments are shown. The concepts claimed and described herein may, however, be embodied in many different forms and should not be construed as limited to the example embodiments set forth herein; rather, these embodiments are provided so that this disclosure will be thorough and complete, and will fully convey the scope of the claimed invention to those skilled in the art. Like numbers refer to like, but not necessarily the same, elements throughout.

Certain dimensions and features of the example solar cell arrangement on a vehicle are described herein using the term “approximately.” As used herein, the term “approximately” indicates that each of the described dimensions is not a strict boundary or parameter and does not exclude functionally similar variations therefrom. Unless context or the description indicates otherwise, the use of the term “approximately” in connection with a numerical parameter indicates that the numerical parameter includes variations that, using mathematical and industrial principles accepted in the art (e.g., rounding, measurement or other systematic errors, manufacturing tolerances, etc.), would not vary the least significant digit.

In addition, certain relationships of the solar cell arrangement on a vehicle are described herein using the term “substantially.” As used herein, the terms “substantially” and “substantially equal” indicates that the relationship or equal relationship is not a strict relationship and does not exclude functionally similar variations therefrom. Unless context or the description indicates otherwise, the use of the term “substantially” or “substantially equal” in connection with two or more described dimensions or elements indicates that the equal relationship between the dimensions or elements includes variations that, using mathematical and industrial principles accepted in the art (e.g., rounding, measurement or other systematic errors, manufacturing tolerances, etc.), would not vary the least significant digit of the dimensions or elements. As used herein, the term “substantially constant” indicates that the constant relationship is not a strict relationship and does not exclude functionally similar variations therefrom. As used herein, the term “substantially parallel” indicates that the parallel relationship is not a strict relationship and does not exclude functionally similar variations therefrom. As used herein, the terms “substantially perpendicular” and “substantially orthogonal” indicate that the perpendicular relationship is not a strict relationship and does not exclude functionally similar variations therefrom.

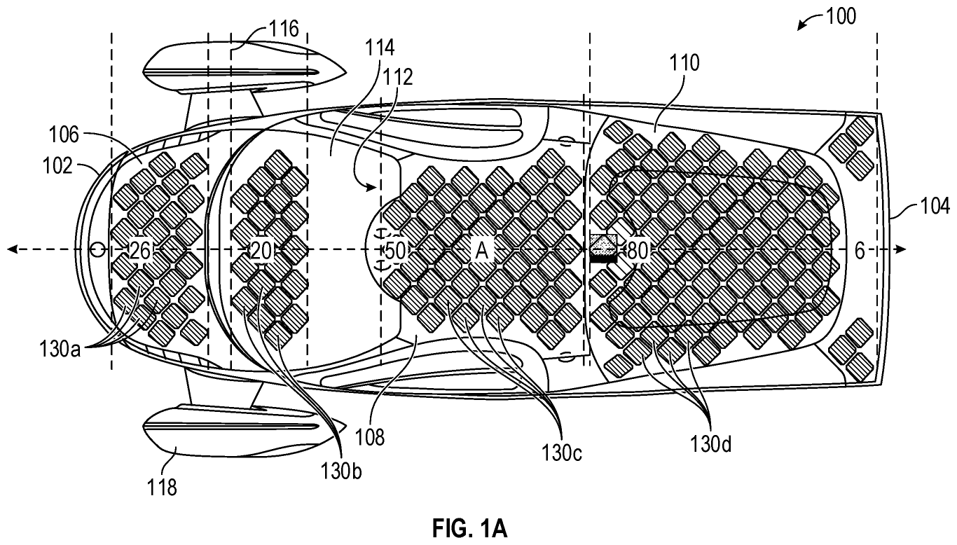

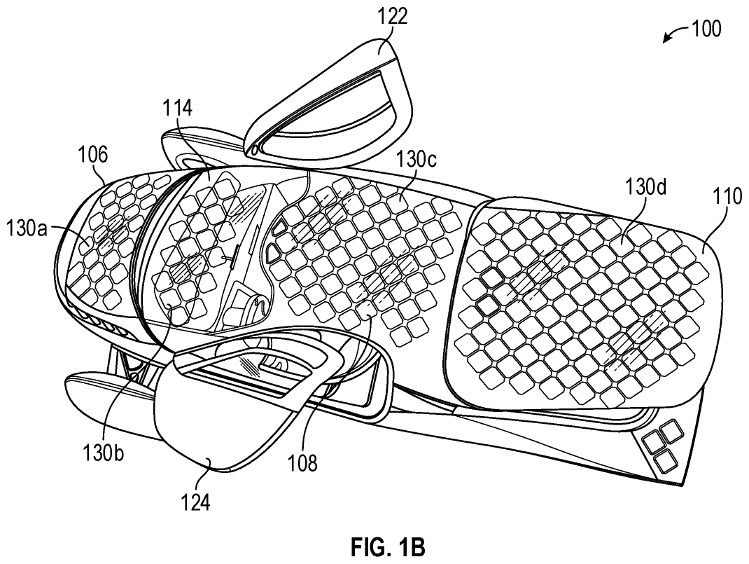

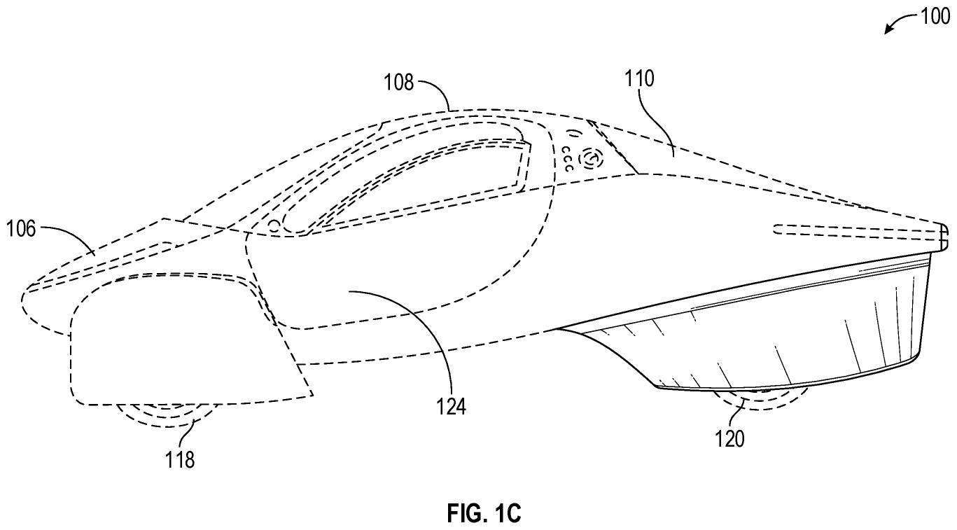

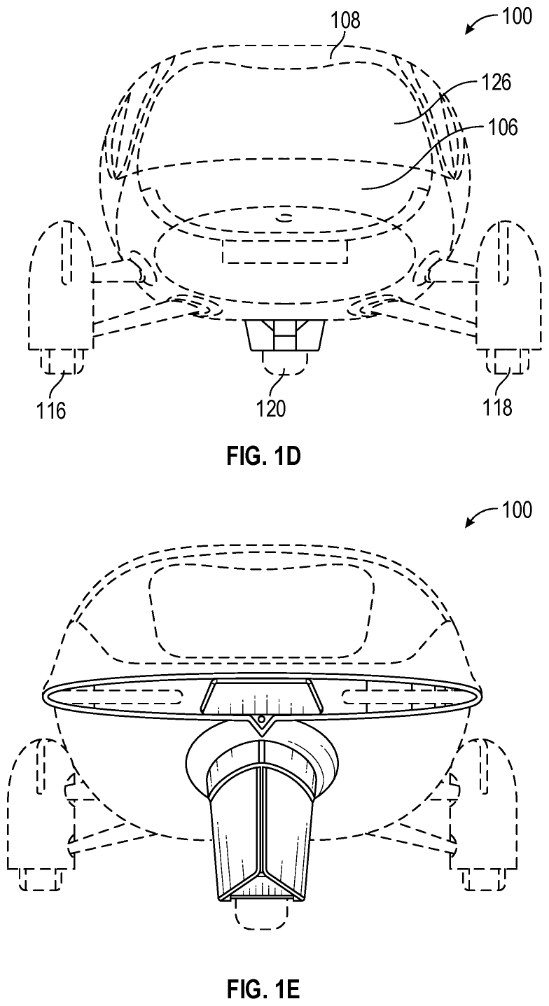

FIGS. 1A-1E present various views of a solar powered vehicle 100, in accordance with one example embodiment of the disclosure. The term vehicle, as used herein, may refer to any suitable type of automobile, including a consumer vehicle (e.g., sedan, sport utility vehicle, etc.), commercial vehicle (e.g., delivery truck, tractor trailer, etc.), and/or a recreational vehicle. As discussed above, one or more panels that form the exterior of the solar powered vehicle may include one or more solar cells. The one or more panels of the vehicle 100 having one or more solar cells may include any suitable components of the solar car, such as a roof, hood, trunk lid, door, side panel, windshield, window, sunroof, and/or other body panel.

Referring to FIGS. 1A-1E, the solar powered vehicle 100 can include a front end 102 and a distal rear end 104. A longitudinal axis A for the vehicle 100 can extend from the front end 102 to the rear end 104. The vehicle 100 can also include a hood panel 106, a roof panel 108, and a rear hatch panel 110. In certain examples, each of the hood panel 106 and rear hatch panel 110 are pivotable with respect to another portion of the vehicle frame from an open position to a closed position. In addition, the rear hatch panel 110 can include one or more cameras communicatively coupled to a display in the vehicle interior 112 for providing a view of the environment behind the vehicle. The vehicle 100 also includes a vehicle interior 112. The vehicle interior 112 can include one or more passenger seats, a steering wheel, a dashboard 114 and other components found in conventional automobiles and known to those of ordinary skill in the art.

The vehicle 100 can also include wheels for moving the vehicle along a road surface. In one example, the vehicle 100 can include a first front wheel 116 positioned along one lateral side of the vehicle and a second front wheel 118 positioned along a second lateral side of the vehicle opposite the first lateral side. The vehicle 100 can also include a rear wheel 120. The rear wheel 120 can be centrally positioned along the rear 104 of the vehicle 100 between the first and second lateral sides. While three wheels 116-120 are shown, this is for example purposes only as more than three wheels can be provided in other example embodiments. For example, two rear wheels can be provided, each positioned along one of the first and second lateral sides of the vehicle 100.

The vehicle 100 can also include one or more doors for accessing the vehicle interior 112. In one example, the vehicle includes a first door 122 positioned along the first lateral side of vehicle 100 and a second door 124 positioned along the second lateral side of the vehicle 100. In other examples, more or less than two doors 122, 124 can be provided on the vehicle 100. Each door 122, 124 can be hingedly coupled to the vehicle frame and can be adjusted from an open position, providing access to the vehicle interior 112 from the exterior of the vehicle 100, to a closed position, preventing access to the vehicle interior 112 from the exterior of the vehicle 100. The vehicle 100 can also include a windshield 126 positioned between the hood panel 106 and the roof panel 108 and disposed at least partially above the dashboard 114.

The vehicle 100 can also include multiple solar cells 130. Solar cells 130 can be any solar cell known in the art provided it is sufficiently flexible. For example, solar cells 130 may be amorphous silicon (a-Si) solar cells, cadmium telluride (CdTe) solar cells, concentrated photovoltaic (CPV) solar cells, copper indium gallium selenide (CI(G)S) solar cells, gallium arsenide germanium (GaAs) solar cells, monocrystalline (mono-Si) solar cells, polycrystalline (multi-Si) solar cells, quantum dot solar cells, solid-state solar cells, thin-film (TFSC) solar cells, or another suitable type of solar cell. For example, solar cells 130 can be MAXEON™ GEN III solar cells from SunPower Corporation, San Jose, Calif., USA.

In one example, the vehicle 100 can include a first group of solar cells 130a disposed along the top surface of the hood panel 106. In one example, the number of solar cells 130 disposed on the hood panel 106 can be greater than 10 and preferably greater than 20 and more preferably greater than 25. In certain examples, twenty-six solar cells 130 are in the first group of solar cells 130a disposed on the hood panel 106 of the vehicle. However, greater or lesser numbers of solar cells 130 may be included in the first group 130a and the number can be affected by a change in the size and/or shape of each individual cell 130.

The vehicle 100 can also include a second group of solar cells 130b disposed along the top surface of the dashboard 114. In one example, the number of solar cells 130 disposed on the dashboard 114 can be greater than 5 and preferably greater than 10 and more preferably greater than 15. In certain examples, twenty solar cells 130 are in the second group of solar cells 130b disposed on the dashboard 114 of the vehicle 100. However, greater or lesser numbers of solar cells 130 may be included in the second group 130b and the number can be affected by a change in the size and/or shape of each individual cell 130 and the top surface area of the dashboard 114.

The vehicle 100 can also include a third group of solar cells 130c disposed along the top surface of the roof panel 108. In one example, the number of solar cells 130 disposed on the roof panel 108 can be greater than 10 and preferably greater than 20 and more preferably greater than 25. In certain examples, thirty solar cells 130 are in the third group of solar cells 130c disposed on the roof panel 108 of the vehicle 100. However, greater or lesser numbers of solar cells 130 may be included in the third group 130c and the number can be affected by a change in the size and/or shape of each individual cell 130 and the top surface area of the roof panel 108.

The vehicle 100 can also include a fourth group of solar cells 130d disposed along the top surface of the rear hatch panel 110. In one example, the number of solar cells 130 disposed on the rear hatch panel 110 can be greater than 30 and preferably greater than 50 and more preferably greater than 70. In certain examples, eighty solar cells 130 are in the fourth group of solar cells 130d disposed on the rear hatch panel 110 of the vehicle 100. However, greater or lesser numbers of solar cells 130 may be included in the fourth group 130d and the number can be affected by a change in the size and/or shape of each individual cell 130 and the top surface area of the rear hatch panel 110.

Each of the solar cells 130 may be coupled to the respective portions of the vehicle 100 described above with the use of adhesive or another bonding material. One of a number of coating materials known to those of ordinary skill in the art may then be applied to the top surface of the solar cells 130 to protect the solar cells 130 from environmental contaminants. In certain examples, the coating material can have other features, such as anti-reflective features. For example, an anti-reflective feature would be useful on the solar cells 130 in the second group 130b to prevent a glare on the windshield 126. The solar cells 130 may be electrically coupled in series and/or in parallel to other solar cells 130 on the vehicle.

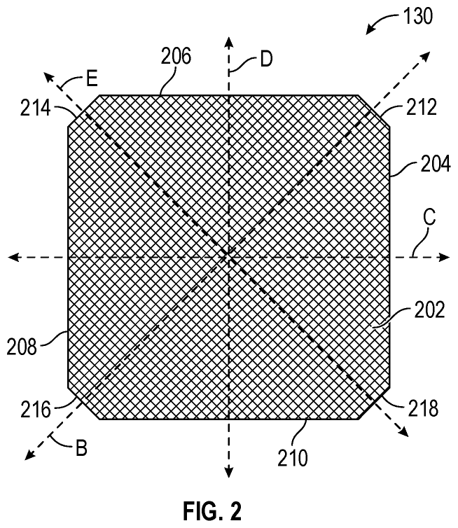

FIG. 2 is a top plan view of a solar cell 130 for use with the solar powered vehicle 100 of FIG. 1A, in accordance with one example embodiment of the disclosure. Referring now to FIGS. 1A-2, in one example, each solar cell 130 can have a generally rectangular shape with the corners either cut off or radiused to reduce the potential for breaking the corner areas of the solar cell 130, which tend to be weak points. The example solar cell 130 of FIG. 2 is an in irregular octagon created by removal of the corners of a generally rectangular (e.g., square) cell 130. For example, the solar cell 130 can have a cell body 202 that has a first long edge 204, a second long edge 206, a third long edge 208, and a fourth long edge 210. The first long edge 204 and the third long edge 208 are parallel or substantially parallel to one another and orthogonal or substantially orthogonal to the second long edge 206 and the fourth long edge 210.

In certain examples, the solar cell 130 can have corners at the junction of the first long edge 204 and second long edge 206, the second long edge and the third long edge 208, the third long edge 208 and the fourth long edge 210, and the fourth long edge 210 and the first long edge 204. In other examples, the solar cell 130 can include a first short edge 212 extending from the first long edge 204 to the second long edge 206, a second short edge 214 extending from the second long edge 206 to the third long edge 208, a third short edge 216 extending from the third long edge 208 to the fourth long edge 210, and a fourth short edge 218 extending from the fourth long edge 210 to the first long edge 204.

The solar cell 130 can have an axis of symmetry B that bisects the first corner and third corner or first short edge 212 and the third short edge 216, an axis of symmetry E that bisects the second corner and fourth corner or the second short edge 214 and the fourth short edge 218, an axis of symmetry C that bisects the first long edge 204 and the third long edge 208, and an axis of symmetry D that bisects the second long edge 206 and the fourth long edge 210. The solar cell 130 has limited flexibility along its axes of symmetry C and D. Along the axes of symmetry B and E, the solar cell 130 has greater flexibility than along each of its axes of symmetry C and D. In certain examples, the solar cell 130 is at least 30% more flexible along the axes of symmetry B and E than along the axes of symmetry C and D.

While conventional vehicles would apply the solar cells with the long edges 204-210 being parallel and orthogonal to the longitudinal axis A of the vehicle, given the improved flexibility along the axes of symmetry B and E, the solar cells are applied on the vehicle at an angle greater than zero degrees to about forty-five degrees, or at substantially forty-five degrees to the longitudinal axis A of the vehicle 100. In this forty-five degree offset, one of the short edges 212-218 faces the front end 102 of the vehicle 100 and another one of the short edges 212-218 faces the rear 104 of the vehicle 100. In this layout, one of the axes of symmetry B and E is parallel or substantially parallel to the longitudinal axis A of the vehicle 100 and the other one of the axes of symmetry B and E is orthogonal or substantially orthogonal to the longitudinal axis A of the vehicle. Further, in this forty-five degree offset, each of the long edges 204-210 extend at a forty five degree offset to the longitudinal axis A of the vehicle. In this layout, additional solar cells 130 are applied such that one of the short edges 212-218 of a second solar cell 130 are placed adjacent one of the short edges 212-218 of the first solar cell 130. This layout results in a diamond or argyle design for the solar cells 130 along the surface of the vehicle 100.

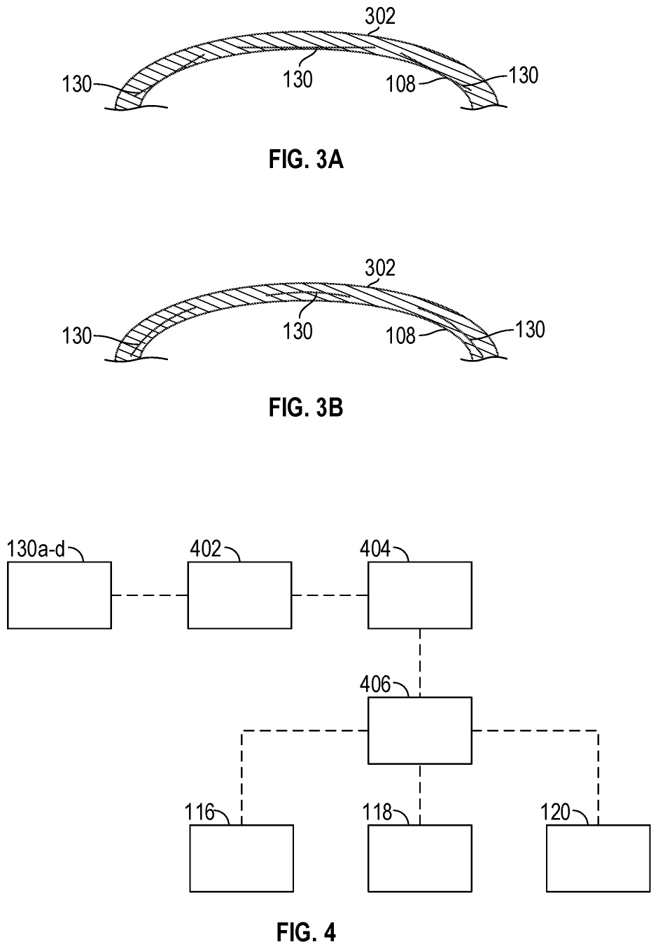

As depicted in FIG. 3A, solar cells 130 may be substantially linear when arranged on a body panel, such as roof panel 108. Due to the curvature of the roof panel 108, such an arrangement and choice of solar cell may result in one or more edges of the solar cells 130 to be raised relative to the roof panel. In some embodiments, an encapsulation layer 302 may be applied to the solar cells 130, creating a smooth external surface while protecting the solar cells 130. The encapsulation layer may be any suitable material. For example, encapsulation layer 302 may be a pourable or paintable curable resin, a sheet of curable resin, a rigid plastic or glass panel, or the like.

As depicted in FIG. 3B, the solar cells 130 may be curved. In some embodiments, the solar cells 130 have a radius of curvature substantially equal to the radius of curvature of the roof panel 108. In some embodiments, each of the solar cells 130 has a unique radius of curvature depending on the curvature of the roof panel 108 at the position the solar cell is positioned. An encapsulation layer 302 may be applied to the solar cells 130, creating a smooth external surface while protecting the solar cells 130.

As shown in FIG. 4, the vehicle 100 can also include one or more batteries 402 electrically coupled to the solar cells 130 and configured to receive the harvested energy from the solar cells 130. The one or more batteries 402 can be positioned along any portion of the vehicle 100. The vehicle 100 can also include an electric motor 404 electrically coupled to the one or more batteries 402 and/or the solar cells 130. The electric motor 404 can be operably coupled to a drive system 406 for the vehicle to provide a drive torque to one or more of the wheels 116-120. The vehicle 100 can also include any other components found in conventional automobiles. These components are known to those of ordinary skill in the art and are within the capability of those skilled in the art to add to the vehicle 100 as desired.

Though the disclosed examples include a particular arrangements of a number of parts, components, features, and aspects, the disclosure is not limited to only those examples or arrangements. Any one or more of the parts, components, features, and aspects of the disclosure can be employed alone or in other arrangements of any two or more of the same.

Although certain features, functions, components, and parts of the solar powered vehicle 100 have been described herein in accordance with the teachings of the present disclosure, the scope of coverage of this patent is not limited thereto. On the contrary, this patent covers all embodiments of the teachings of the disclosure that fairly fall within the scope of permissible equivalents.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language generally is not intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A vehicle comprising:
a vehicle body having a longitudinal axis and comprising:
a hood panel;
a roof panel;
a rear hatch panel; and
at least one door;
a plurality of wheels movably coupled to the vehicle body; and
a plurality of solar cells disposed along the vehicle body, wherein at least a first solar cell of the plurality of solar cells has at least one long edge, and wherein the at least one long edge is disposed at a first acute angle relative to the longitudinal axis of the vehicle body, wherein the first acute angle is greater than zero degrees to about forty-five degrees.

2. The vehicle of claim 1, wherein the first acute angle is substantially forty-five degrees.

3. The vehicle of claim 2, wherein all of the solar cells are disposed at the first acute angle relative to the longitudinal axis.

4. The vehicle of claim 1, further comprising an encapsulation layer on the plurality of solar cells.

5. The vehicle of claim 4, wherein the encapsulation layer fills in at least one space between at least two solar cells in the plurality of solar cells to produce a smooth surface.

6. The vehicle of claim 1, further comprising an interior compartment and a dashboard within the interior compartment, wherein at least a portion of the plurality of solar cells is disposed along a top surface of the dashboard.

7. The vehicle of claim 1, wherein each of the plurality of solar cells has an irregular octagon shape having four long edges alternating with four short edges.

8. The vehicle of claim 7, wherein each of the plurality of solar cells has two axes of symmetry bisecting the long edges of the solar cell, and two axes of symmetry bisecting the short edges of the solar cell.

9. The vehicle of claim 8, wherein each of the plurality of solar cells is at least 30% more flexible along the axes of symmetry bisecting the short edges of the solar cell than along the axes of symmetry bisecting the long edges of the solar cell.

10. The vehicle of claim 1, wherein at least one solar cell of the plurality of solar cells is disposed on the hood panel of the vehicle.

11. The vehicle of claim 1, wherein at least one solar cell of the plurality of solar cells is disposed on the roof panel.

12. The vehicle of claim 1, wherein at least one solar cell of the plurality of solar cells is disposed on the rear hatch panel.

13. The vehicle of claim 1, further comprising one or more batteries electrically coupled to the plurality of solar cells and configured to receiving energy harvested from the solar cells.

14. The vehicle of claim 12, wherein the rear hatch panel further comprises at least one camera.

15. A body panel for installation on a vehicle, the body panel comprising a plurality of solar cells disposed along an outer surface of the body panel, wherein at least a first solar cell of the plurality of the solar cells has at least one long edge, and wherein the at least one long edge is disposed at a first acute angle relative to a longitudinal axis of the body panel.

16. The body panel of claim 15, wherein the first acute angle is substantially forty-five degrees.

17. The body panel of claim 16, wherein all of the solar cells are disposed at the first acute angle relative to the longitudinal axis.

18. The body panel of claim 15, further comprising an encapsulation layer on the plurality of solar cells.

19. The body panel of claim 15, wherein the body panel is a hood panel, a roof panel, a rear hatch panel, or a door panel.

20. A method of integrating solar cells with a vehicle, the method comprising:
providing a body panel;
attaching a plurality of solar cells to an outer surface of the body panel, wherein at least a first solar cell of the plurality of solar cells has at least one long edge disposed at a first acute angle relative to a longitudinal axis of the body panel; and
integrating the body panel on the vehicle.

21. The method of claim 20, further comprising:
encapsulating the plurality of solar cells with an encapsulation layer that fills in at least one space between at least two solar cells in the plurality of solar cells.

22. The method of claim 20, wherein the body panel is a hood panel and the step of integrating the body panel on the vehicle comprises integrating the body panel on a hood of the vehicle.

23. The method of claim 20, wherein the body panel is a roof panel and the step of integrating the body panel on the vehicle comprises integrating the body panel on a roof of the vehicle.

24. The method of claim 20, wherein the body panel is a rear hatch panel and the step of integrating the body panel on the vehicle comprises integrating the body panel on a rear hatch of the vehicle.

25. The method of claim 20, wherein the body panel is a door panel and the step of integrating the body panel in the vehicle comprises integrating the body panel on a door of the vehicle.
